(19) United States
(12) Patent Application Publication
(10) Pub. No.: US 2023/0367223 A1
(43) Pub. Date: Nov. 16, 2023

(54) SUBSTRATE PROCESSING COMPOSITION AND SUBSTRATE PROCESSING METHOD USING THE SAME

(71) Applicant: SK Inc., Seoul (KR)

(72) Inventors: Jinseok YANG, Sejong-si (KR); Suyeon JO, Sejong-si (KR); Junghwan HAH, Sejong-si (KR)

(73) Assignee: SK Inc., Seoul (KR)

(21) Appl. No.: 18/143,400

(22) Filed: May 4, 2023

(30) Foreign Application Priority Data
May 10, 2022 (KR) 10-2022-0057150

(51) Int. Cl. G03F 7/42; G03F 7/004; G03F 7/20

(52) U.S. Cl. CPC G03F 7/422; G03F 7/0042; G03F 7/2004

(57) ABSTRACT

There is provided a substrate processing composition for processing a substrate coated with a metal-containing resist composition. The substrate processing composition includes an organic solvent, an organic acid, and an additive. The additive includes a chelating agent made of quercetin and a derivative thereof and the content of the additive ranges 0.1 to 10% by mass relative to the total mass of the substrate processing composition.

### CROSS-REFERENCE TO PRIOR APPLICATION

This application claims priority to Korean Patent Application No. 10-2022-0057150 (filed on May 10, 2022), which is hereby incorporated by reference in its entirety.

### BACKGROUND

The present invention relates to a composition for processing a substrate and a method for processing the substrate using the composition, and more particularly to the composition for processing the substrate coated with a metal-containing resist composition and the method for processing the substrate using the same.

The development of electronic technologies has rapidly down-scaled semiconductor devices in terms of pattern size. For down-scaling of semiconductor devices, extreme ultraviolet (EUV) or electron beam lithography technology is being actively researched and applied to mass production.

However, in lithography using extreme ultraviolet or electron beam radiation, conventional resin-based chemically amplified resists cannot meet all the demands of resolution, sensitivity, and pattern roughness, and a new resist which can achieve simultaneous improvements in all of resolution, sensitivity, and pattern roughness has been greatly studied.

In particular, as a resist promising for extreme ultraviolet lithography or electron beam lithography, a metal-containing resist is gathering great interests. Because the metal-containing resist provides good absorption of extreme ultraviolet light and electron beam radiation, while simultaneously providing very high etch contrast, application in mass production of semiconductor devices is greatly anticipated.

With the introduction of such a new resist composition, the development of a new technology capable of suppressing contamination by metal contained in the metal-containing resist composition during an edge rinsing step for removing edge beads formed on an edge portion of a substrate in the lithography process using the metal-containing resist composition and the resulting deterioration of the electrical properties of the semiconductor device is required.

In addition, it is desired that influence on an underlying film on the substrate by an edge rinsing solution used in the edge rinsing step should be reduced and that stability (solubility) over time of the edge rinsing solution should be improved.

### SUMMARY

The objective of the present invention is to suppress contamination due to metal derived from the metal-containing resist composition during the edge rinsing step or a subsequent substrate cleaning step in the lithography process using the metal-containing resist composition and the resulting deterioration of electrical characteristics of the semiconductor device, and to provide a substrate processing composition and a substrate processing method which is improved in terms of the influence on the underlying film or the stability over time (solubility).

A substrate processing composition according to a first aspect of the present invention is a composition for processing a substrate coated with a metal-containing resist composition, the substrate processing composition comprising:
an organic solvent, an organic acid and an additive,
wherein the additive includes a chelating agent represented by Chemical Formula 1 below.

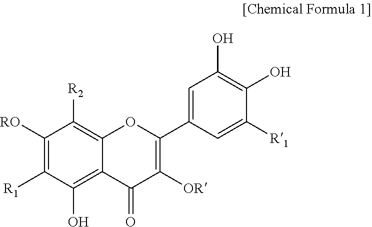

(In Chemical Formula 1,
R₁, R₂ and R′₁ are the same or different at each instance, and independently represent hydrogen or a hydroxyl group,
R and R′ are the same or different at each instance, and independently represent hydrogen, a sulfate group, or a substituted or unsubstituted C1-C30 aliphatic or aromatic hydrocarbon group, and
at least one hydrogen in R and R′ may be substituted by a hydroxyl group.)

A substrate processing method according to a second aspect of the present invention comprises steps of: applying a metal-containing resist composition on a substrate; processing the substrate using the substrate processing composition according to the first aspect of the present invention; and forming a pattern of a metal-containing resist film on the substrate.

According to the substrate processing composition and the substrate processing method pertaining to the technical spirit of the present invention, in the lithography process using the metal-containing resist composition, substrate contamination and equipment contamination due to metal derived from the metal-containing resist composition can be suppressed, thereby increasing process efficiency, and deterioration of electrical properties of semiconductor devices can be prevented. In addition, the influence on the underlying film such as a nitride film or a polysilicon film can be reduced, and the stability over time (solubility) can be improved.

### BRIEF DESCRIPTION OF THE DRAWINGS

FIG. 1 is a flowchart for explaining the substrate processing method according to embodiments pertaining to the technical spirit of the present invention.

FIG. 2 is a flowchart for explaining the substrate processing method according to other embodiments pertaining to the technical spirit of the present invention.

### DETAILED DESCRIPTION

Hereinafter, embodiments of the present invention will be described in detail with reference to the accompanying drawings. The same reference numerals are used for the same components in the drawings, and duplicate descriptions thereof are omitted.

According to one embodiment of the present invention, a composition that can be used in a step of processing a substrate coated with a metal-containing resist composition, such as an edge rinsing step and/or a post-cleaning processing of the substrate, is provided.

In the present disclosure, the metal-containing resist composition may include a metal structure containing an organometallic compound, organometallic nanoparticles, or organometallic clusters, and an organic solvent.

The metal structure included in the metal-containing resist composition may include a metal core containing at least one metal atom and at least one organic ligand coordinating the metal core. An ionic bond, a covalent bond, a metallic bond, or a van der Waals bonds may be present between the metal core and the organic ligand.

The metal core may contain at least one metal element including a metal atom, a metallic ion, a metal compound, a metal alloy, or a combination thereof. The metal compound may be formed of metal oxide, metal nitride, metal oxynitride, metal silicide, metal carbide, or a combination thereof. In exemplary embodiments, the metal core may contain at least one metal element selected from tin (Sn), stibium (Sb), indium (On), bismuth (Bi), silver (Ag), tellurium (Te), gold (Au), plumbum (Pb), zinc (Zn), titanium (Ti), hafnium (Hf), zirconium (Zr), aluminum (Al), vanadium (V), chrome (Cr), cobalt (Co), nickel (Ni), copper (Cu), gallium (Ga), and iron (Fe), but, the technical sprit of the present invention is not limited thereto.

The organic ligand may include C1-C30 linear alkyl, C1-C30 branched alkyl. C3-C30 cycloalkyl, C2-C30 alkenyl, C2-C30 alkynyl, C6-C30 aryl, C3-C30 allyl, C1-C30 alkoxy, C6-C30 aryloxy, or a combination thereof. The organic ligand may contain a hydrocarbyl group substituted by at least one heteroatom functional group including an oxygen atom, a nitrogen atom, a halogen atom, cyano, thio, silyl, ether, carbonyl, ester, intro, amino, or a combination thereof. The halogen atom may be fluorine (F), chlorine (Cl), bromine (Br), or iodine (I).

For example, the organic ligand may include methyl, ethyl, propyl, butyl, isopropyl, third butyl, third amyl, second butyl, cyclopropyl, cyclobutyl, cyclopentyl, or cyclohexyl.

The metal structure may include a plurality of organic ligands, and two organic ligands among the plurality of organic ligands may form one cyclic alkyl moiety. The cyclic alkyl moiety may include 1-adamantyl or 2-adamantyl.

In one embodiment of the present invention, the metal-containing resist composition may contain tin (Sn) as a metal element.

For example, a tin-containing resist composition is a composition represented by the formula R_{z}SnO_{(2-(z/2)-(x/2))}(OH)ₓ (where 0<z≤2 and 0<(z+x)≤4, and R is a C1-C31 hydrocarbyl group). At least some of the oxo/hydroxo ligands can be formed to be a composition represented by the formula RₙSnX4-ₙ, by in situ hydrolysis following deposition on the substrate. Herein, X may include alkynides RC≡C, alkoxides RO—, azides N₃—, carboxylates RCOO—, halides and dialkylamides. Furthermore, some of the R_{z}SnO_{(2-(z/2)-(x/2))}(OH)x composition can be substituted with MO_{((m/2)-l/2)}(OH)ₗ where m=formal valence of M^{m+}, 0≤l≤m, y/z=(0.05 to 0.6), and M=M′ or Sn, where M′ is a non-tin metal of groups 2-16 of the periodic table).

Thus, the metal-containing resist composition coated on the substrate being processed by the substrate processing method according to one embodiment of the present invention can comprise R_{z}SnO_{(2-(z/2)-(x/2))}(OH)ₓ, R′ₙSnX₄₋ₙ, and/or MO_{((m/2)-l/2)}(OH)ₗ, may further comprises compositions having metal carboxylate bonds (e.g., ligands of acetate, propanoate, butanoate, benzoate, and/or the like), such as dibutyltin diacetate.

In exemplary embodiments, the metal structure may be formed of (tBu)Sn(NEt₂)₂(OtBu), (tBu)Sn(NEt₂)(NH₂)(OtBu), (tBu)Sn(NEt₂)(OtBu)₂, (Me)Sn(NEt₂)(OtBu)₂, (Me)Sn(NEt₂)₂(OtBu), (tBu)₂Sn(NEt₂)(OtBu), (Me)₂Sn(NEt₂)(OtBu), (Me)(tBu)Sn(NEt₂)₂, (Me)(tBu)Sn(NEt₂)(OtBu), (iPr)(tBu)Sn(NMe₂)(OtBu) or a combination thereof, but, the technical spirit of the present invention is not limited thereto. Here, “Me” means methyl, “Et” means ethyl, and “tBu” means tertiary butyl.

The organic solvent included in the metal-containing resist composition may include at least one of ether, alcohol, glycol ether, an aromatic hydrocarbon compound, ketone, and ester, but the technical spirit of the present invention is not limited thereto. For example, the organic solvent may be formed of, ethylene glycol monomethyl ether, ethylene glycol monoethyl ether, methyl cellosolve acetate, ethyl cellosolve acetate, diethylene glycol methyl ether, diethylene glycol ethyl ether, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, hexanol, 1-methoxy-2-propanol, 1-etholy-2-propanol, ethylene glycol, propylene glycol, heptanone, propyl carbonate, butylene carbonate, toluene, xylene, methyl ethyl ketone, cyclopentanone, cyclohexanone, ethyl 2-hydroxy propionate, ethyl 2-hydroxy-2-methyl propionate, ethyl ethoxyacetate, ethyl hydroxylacetate, methyl 2-hydroxy-3-methyl butanoate, methyl 3-methoxy propionate, ethyl 3-methoxy propionate, ethyl 3-ethoxy propionate, methyl 3-ethoxy propionate, methyl pyruvate, ethyl pyruvate, ethyl acetate, butyl acetate, ethyl lactate, butyl lactate, gamma-butyrolactone, methyl-2-hydroxyisobutyrate, methoxybenzene, n-butyl acetate, 1-methoxy-2-propyl acetate, methoxy ethoxy propionate, ethoxy ethoxy propionate, or a combination thereof.

When such a metal-containing resist composition is applied onto a substrate, clusters of metal peroxide may bond to the surface of the substrate such as a silicon wafer to form a residue.

However, the conventional cleaning composition for edge-rinsing a resin-based resist composition cannot sufficiently remove residues caused by clusters of these metal peroxides.

Therefore, in one embodiment of the present invention, in order to improve the removability of the metal contained in the coated film of the metal-containing resist composition, a substrate processing composition comprising an organic solvent, an organic acid, and a chelating additive represented by Chemical Formula 1 is provided.

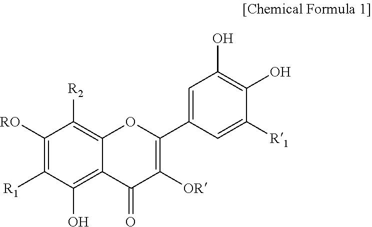

In Chemical Formula 1,
R₁, R₂ and R′₁ are the same or different at each instance, and independently represent hydrogen or a hydroxyl group,
R and R′ are the same or different at each instance, and independently represent hydrogen, a sulfate group, or a substituted or unsubstituted C1-C30 aliphatic or aromatic hydrocarbon group, and at least one hydrogen in R and R′ may be substituted by a hydroxyl group.

Because the chelating additive represented by Chemical Formula 1 commonly has, as shown below, at least three chelating sites (3-hydroxy-carbonyl group, 5-hydroxy-carbonyl group and 3′,4′-dihydroxyl group) in the molecule.), it can significantly improve metal (e.g., tin) removability compared to other chelating agents. In addition, the influence on the underlying film (nitride film, polysilicon film, etc.) formed on the substrate can be reduced, and stability over time, such as the solubility of the substrate processing composition, can be improved.

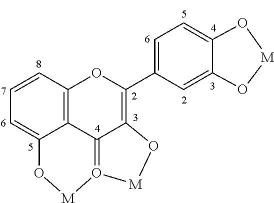

Specific examples of the chelating additive represented by Chemical Formula 1 may include quercetin or derivatives thereof represented by the following formulas.

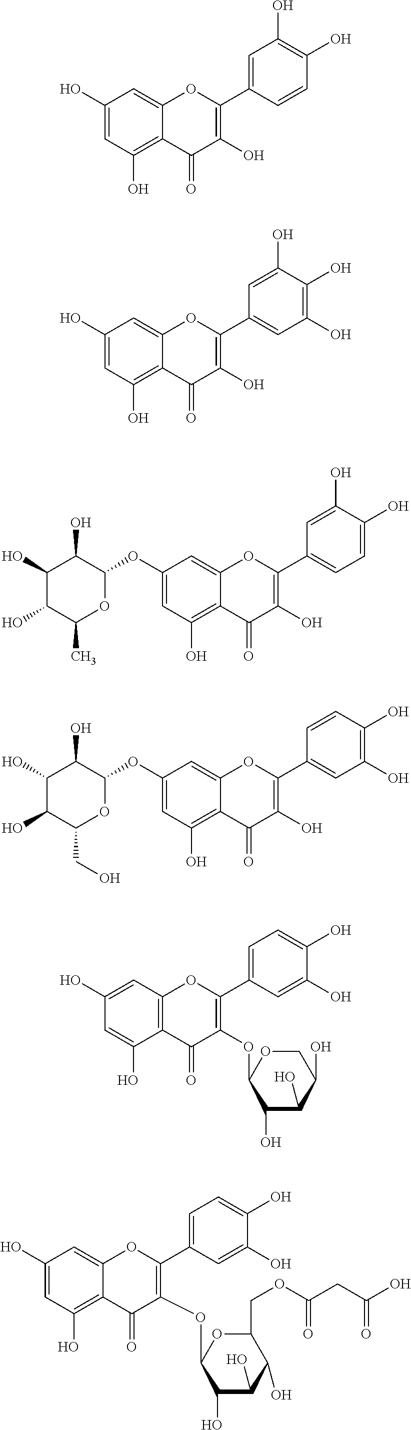

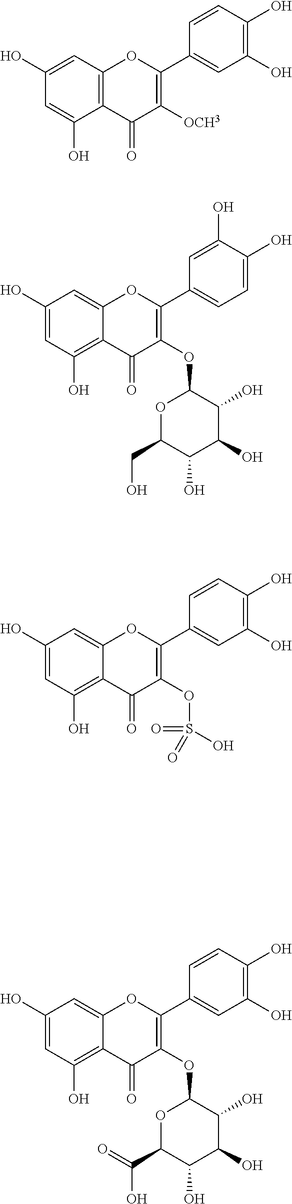 [SMILES: COc1c(-c2ccc(O)c(O)c2)oc2cc(O)cc(O)c2c1=O ; O=c1c(O[C@@H]2O[C@H](CO)[C@@H](O)[C@H](O)[C@H]2O)c(-c2ccc(O)c(O)c2)oc2cc(O)cc(O)c12 ; O=c1c(OS(=O)(=O)O)c(-c2ccc(O)c(O)c2)oc2cc(O)cc(O)c12 ; O=C(O)[C@H]1O[C@@H](Oc2c(-c3ccc(O)c(O)c3)oc3cc(O)cc(O)c3c2=O)[C@H](O)[C@@H](O)[C@@H]1O]

In the substrate processing composition according to one embodiment of the present invention, the content of the chelating additive is preferably 0.1 to 10% by mass, more preferably 0.3 to 5% by mass, and especially preferably 0.5 to 2.5% by mass, relative to the total mass of the substrate processing composition.

The organic acid contained in the substrate processing composition according to one embodiment of the present invention includes carboxylic acids such as formic acid, acetic acid, citric acid, oxalic acid, 2-nitrophenylacetic acid, 2-ethylhexanoic acid, and dodecanoic acid; sugar acids such as ascorbic acid, tartaric acid, and glucuronic acid; sulfonic acids such as methanesulfonic acid, benzenesulfonic acid, and p-toluenesulfonic acid; phosphoric acid esters such as bis(2-ethylhexyl) phosphoric acid; and phosphoric acid and the like.

Especially, as an organic acid, formic acid, acetic acid, and oxalic acid are preferable, and formic acid is more preferable.

In the substrate processing composition according to an embodiment of the present invention, the content of the organic acid is preferably 10 to 60% by mass, more preferably 15 to 55% by mass, and especially preferably 20 to 50% by mass, relative to the total mass of the substrate processing composition.

The organic acid contained in the substrate processing composition of the present invention reacts with the metal in the metal-containing resist composition coated on the substrate to further improve the metal removability from the film of the metal-containing resist composition.

The organic solvent contained in the substrate processing composition according to an embodiment of the present invention includes glycol ethers and esters thereof, such as propylene glycol methyl ether (PGME), propylene glycol methyl ethyl acetate (PGMEA), propylene glycol butyl ether (PGBE), and ethylene glycol methyl ether; alcohols, such as ethanol, propanol, isopropyl alcohol, isobutyl alcohol, hexanol, ethylene glycol and propylene glycol; cyclic esters such as gamma-butyrolactone; esters such as n-butyl acetate and ethyl acetate; ketones such as 2-heptanone: liquid cyclic carbonates such as propylene carbonate and butylene carbonate; and cyclic sulfones such as sulfolane.

Among these examples, the organic solvent is preferably an organic solvent having no hydroxyl group, more preferably glycol ether or ester thereof or ketone, and still more preferably propylene glycol methyl ether (PGME), propylene glycol methyl ethyl acetate (PGMEA).

By using an organic solvent having no hydroxyl group as the organic solvent, it becomes easier to suppress the esterification reaction of the organic acid in the substrate processing composition, and the temporal stability of the substrate processing composition can be improved.

In one embodiment of the present invention, the organic solvent may be used alone, or a mixture of two or more organic solvents may be used. For example, as the organic solvent, propylene glycol methyl ether (PGME) or propylene glycol methyl ethyl acetate (PGMEA) or a mixed solvent thereof may be used. As the mixed solvent, for example, a solvent in which PGME and PGMEA are mixed at a ratio of 7:3 may be used, but is not limited thereto.

In the substrate processing composition according to an embodiment of the present invention, the content of the organic solvent is preferably 40 to 90% by mass, more preferably 45 to 85% by mass, and particularly preferably 50 to 80% by mass, relative to the total mass of the substrate processing composition.

The substrate processing composition according to one embodiment of the present invention may contain other components in addition to the above components within a range that does not impair the effects of the present invention.

Examples of other components may include an inorganic hydrofluoric acid, a tetraalkylammonium compound, and a surfactant.

Examples of the inorganic hydrofluoric acid include hexafluorosilicic acid, hexafluorophosphoric acid, and fluoroboric acid.

Examples of the tetraalkylammonium compound include tetramethylammonium fluoride, tetrabutylammonium fluoride, tetrabutylammonium fluorosilicate, tetramethylammonium bifluoride, tetraethylammonium bifluoride, tetrapropylammonium bifluoride, tetrabutylammonium bifluoride, tetrapentylammonium bifluoride, tetrahexylammonium bifluoride, tetraheptylammonium bifluoride, tetraoctylammonium bifluoride and the like.

Examples of the surfactant include a polyalkylene oxide alkyl phenyl ether surfactant, a polyalkylene oxide alkyl ether surfactant, a block polymer surfactant composed of polyethylene oxide and polypropylene oxide, a polyoxyalkylene distyrenated phenyl ether surfactant, polyalkylene tribenzyl phenyl ether surfactants, and acetylene polyalkylene oxide surfactants.

These other components may be used alone or in combination of two or more.

In the substrate processing composition according to an embodiment of the present invention, the content of these other components is preferably 0 to 10% by mass relative to the total mass of the substrate processing composition.

Hereinafter, a method of processing a substrate using the substrate processing composition according to an embodiment of the present invention will be described with reference to the drawings.

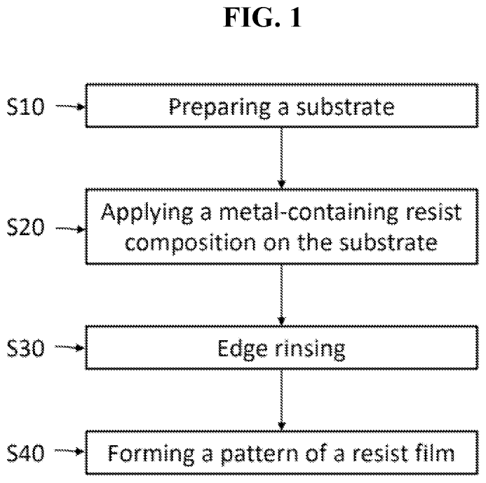

FIG. 1 is a flowchart for explaining a substrate processing method according to an embodiment of the present invention.

Firstly, the substrate such as a wafer made of a semiconductor material is prepared (S10). In exemplary embodiments, the substrate may be formed of a semiconductor element such as silicon (Si) or germanium (Ge), but is not limited thereto. In exemplary embodiments, the substrate may be formed of a compound semiconductor such as SiGe, SiC, GaAs, InAs, or InP, The substrate may have a silicon on insulator (SOI) structure. The substrate may be a bare substrate or may include an underlying film such as an insulating film or a conductive film. The underlying film, for example, may be formed of metal an alloy, metal carbide, metal nitride, metal oxynitride, metal oxycarbide, a semiconductor, polysilicon, oxide, nitride, oxynitride, or a combination thereof, but is not limited thereto. For example, the underlying film may be an anti-reflection film.

In step S20, a resist film is formed by applying the metal-containing resist composition on the substrate. The application of the metal-containing resist composition is usually performed by a spin coating method in which a liquid metal-containing resist composition is dropped on the substrate rotating at a predetermined rotational speed, and the liquid metal-containing resist composition spreads toward the edge of the substrate by centrifugal force and is coated.

In this step, an edge bead in which the film thickness of the metal-containing resist composition at the edge portion of the substrate is thicker than that of the other potions is generated, and in some cases, the metal-containing resist composition may be coated even on the side surface or the back surface of the substrate.

Accordingly, in the substrate processing method according to an embodiment of the present invention, an edge rinsing step S30 (edge bead removal step) for removing edge beads formed on the edge portion of the substrate is performed using the substrate processing composition according to an embodiment of the present invention.

For example, by supplying the substrate processing composition of the present invention to the edge portion of the substrate to remove the edge bead portion of the metal-containing resist film, a surface of the edge portion of the substrate is exposed at the peripheral portion of the metal-containing resist film (the peripheral portion in the radial direction from the center of the substrate).

In the edge rinsing step S30 of the substrate processing method according to an embodiment of the present invention, the substrate processing composition is dropped preferably in an amount of 0.05 to 50 ml, more preferably 0.075 to 40 ml, and still more preferably 0.1 to 25 ml.

In another embodiment, in the edge rinsing step S30, the substrate processing composition may be preferably applied at a flow rate of 5 ml/min to 50 ml/min, preferably for 1 second to 5 minutes, more preferably for 5 seconds to 2 minutes.

According to the substrate processing method pertaining to an embodiment of the present invention, since the substrate processing composition used in the edge rinsing step S30 contains the chelating additive having at least three or more chelating sites, metal removability is improved and, thus, the amount of metallic impurities remaining on the exposed surface (or the underlying film) of the substrate after the edge rinsing step S30 can be reduced.

In order to evaluate metal removability by the substrate processing method according to an embodiment of the present invention, residual metal on the substrate may be inspected using inductively coupled plasma mass spectrometry (ICP-MS). In one embodiment of the present invention, in the case where the metal-containing resist composition contains tin as a metal element, the amount of residual tin is preferably 100×10¹⁰ atoms/cm² or less, more preferably 90×10¹⁰ atoms/cm² or less, and particularly preferably 80×10¹⁰ atoms/cm² or less.

The edge rinsing step S30 (which may include a back rinsing step for removing the metal-containing resist film coated on the back surface of the substrate) of the substrate processing method of the present invention may be performed in a plurality of times to reduce the amount of residual metal impurities to the predetermined value or less (ie, for removal of metal to the desired level). For example, the edge rinsing step S30 may be performed 1 to 20 times.

When the edge rinsing step S30 is performed in a plurality of times, the substrate processing composition used for each time may be the same or two or more different compositions may be used.

After the amount of residual metal becomes less than or equal to the above-mentioned predetermined value by the edge rinsing step S30, an exposure step using an extreme ultraviolet radiation source or an electron beam, a developing step, etc. are performed on the resist film remaining on the substrate to form a resist pattern (S40).

In a resist pattern forming step S40, firstly, the resist film is soft baked at a temperature of about 70° C. to about 150° C. At least a part of the solvent is removed from the resist film by the soft bake so that the resist film can maintain its film shape in subsequent steps.

Then, a partial area of the metal-containing resist film is exposed to an exposure radiation source using a mask having a plurality of blocking areas and a plurality of transmitting areas. As the exposure radiation source, extreme ultraviolet (EUV) or electron beam may be used, but the present invention is not limited thereto, and KrF Excimer laser (248 nm), ArF Excimer laser (193 nm), F₂ excimer laser (157 nm) or the like may also be used.

After exposure, the metal-containing resist film may include an exposed area and a non-exposed area. When the metal-containing resist film is exposed using EUV, photons are absorbed into the metal structure in the metal-containing resist film at the exposed area of the metal-containing resist film so that secondary electrons may be generated in the exposed area.

The secondary electrons may destroy bonds between the organic ligands and the metal core comprising the metal structure in the exposed area so that the metal structures in the exposed area may be clustered to form metal oxide through M-O-M bonds formed of a bond between a metal atom (M) and an oxygen atom (O). For example, in the exposed area of the metal-containing resist film, metal oxide such as SnO₂ may be formed. As a result, the exposed area of the metal-containing resist film has different solubilities to a developer than the non-exposed area of the metal-containing resist film.

After the exposure step, a post exposure bake (PEB) step may be performed at about 70° C. to about 150° C. Then, the exposed resist film is developed with the developer to form a resist pattern.

For example, as the developer, 2-octanone, 2-nonanone, 2-heptanone, 3-heptanone, 4-heptanone, 2-hexanone, 3-hexanone, diisobutyl ketone, methyl cyclohexanone, acetophenone, methyl acetophenone, propyl acetate, butyl acetate, isobutyl acetate, amyl acetate, butenyl acetate, isoamyl acetate, phenyl acetate, propyl formate, butyl formate, isobutyl formate, amyl formate, isoamyl formate, methyl valerate, methyl pentenate, methyl crotonate, ethyl crotonate, methyl propionate, ethyl propionate, 3-ethoxyethyl propionate, methyl lactate, ethyl lactate, propyl lactate, butyl lactate, isobutyl lactate, amyl lactate, isoamyl lactate, 2-hydroxymethyl isobutyrate, ethyl-2-hydroxy isobutyrate, methyl benzoate, ethyl benzoate, phenyl acetate, benzyl acetate, phenylmethyl acetate, benzyl formate, phenylethyl formate, methyl-3-phenylpropionate, benzyl propionate, ethyl phenyl acetate, 2-phenylethyl acetate, or a combination thereof may be used, but the present invention is not limited thereto.

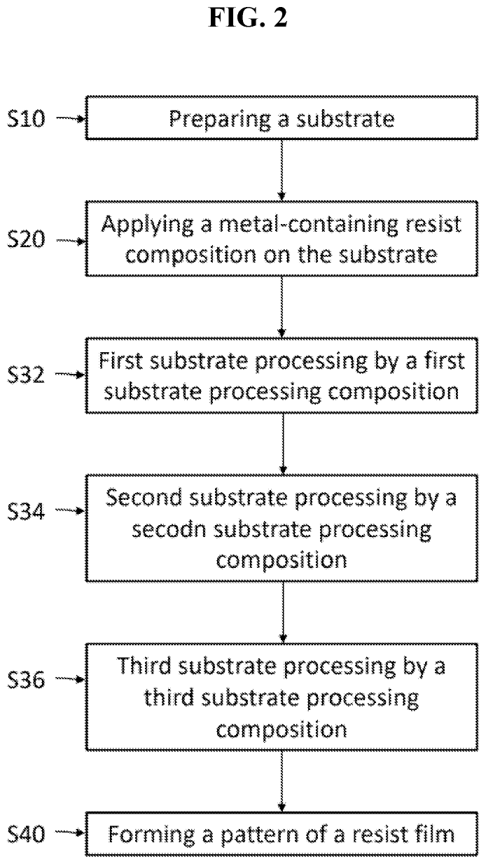

Hereinafter, referring to FIG. 2, a substrate processing method in which an edge rinsing is performed a plurality of times will be described. Herein, an edge rinsing step refers to all steps for cleaning a substrate including an edge bead removal step, which are performed between a step S20 of applying a metal-containing resist composition on the substrate by spin coating and a resist pattern forming step S40 including an exposure step using an extreme ultraviolet radiation source or an electron beam.

In the substrate processing method shown in FIG. 2, a substrate preparation step S10 and a metal-containing resist composition application step S20 are performed in the same manner as in the substrate processing method illustrated in FIG. 1.

Next, in the substrate processing method shown in FIG. 2, unlike the substrate processing method shown in FIG. 1, a first substrate processing step (the edge bead removal step) using a first substrate processing composition, a second substrate processing step using a second substrate processing composition (a first substrate cleaning processing step after the edge bead removal step) and, optionally, a third substrate processing step using a third substrate processing composition (a second substrate cleaning processing step) are performed.

Firstly, in the first substrate processing step S32, the edge bead of the substrate is removed using the first substrate processing composition. The first substrate processing composition used herein may contain an organic solvent. The organic solvent that may be included in the first substrate processing composition is substantially the same as described for the organic solvent that may be contained in the above-described substrate processing composition.

In exemplary embodiments, the organic solvent included in the first substrate processing composition may comprise a mixture of PGME and PGMEA. In this case, the weight ratio of PGME and PGMEA in the organic solvent may be about 3:7 to 5:5, more preferably about 4:6.

In another exemplary embodiments, the first substrate processing composition may comprise a combination of the organic solvent and water.

In another exemplary embodiments, the first substrate processing composition may further comprise at least one selected from a surfactant and a chelating agent.

The surfactant may be a cationic surfactant, an anionic surfactant, or an amphoteric surfactant. For example, the surfactant may be formed of polyethylene glycol tert-octylphenyl ether (Triton™ X-100), nonoxynol-9 (26-(4-nonylphenoxy)-3,6,9,12,15,18,21,24-octaoxahexacosan-1-ol), polysorbate (polyoxyethylene glycol sorbitan alkyl ester), sorbitan alkyl esters (Span®), poloxamers, block copolymer of polyethylene glycol and polypropylene glycol (Tergitol™), dioctyl sodium sulfosuccinate (DOSS), perfluorooctanesulfonate (PFOS), linear alkylbenzene sulfonate, sodium lauryl ether sulfate, lignosulfonate, sodium stearate, benzalkonium chloride (BAC), cetylpyridinium chloride (CPC), benzethonium chloride (BZT), cetyl trimethylammonium bromide (CTAB), cetyl trimethylammonium chloride (CTAC), (3-[(3-cholamidopropyl)dimethylammonio]-1-propanesulfonate) (CHAPS), or a combination thereof, but the present invention is not limited thereto.

The content of the surfactant in the first substrate processing composition may be from about 0.01 mass % to about 15 mass % relative to the total mass of the first substrate processing composition.

By including the surfactant in the first substrate processing composition, it is possible to prevent the portion of the edge bead dissolved by the organic solvent of the first substrate processing composition from being reattached to the substrate, to prevent defects caused by the re-attachment, for example, such as tailing and scum, from occurring.

The chelating agent that may be contained in the first substrate processing composition may be formed of an amino polycarboxylic acid-based chelating agent, an aromatic or aliphatic carboxylic acid-based chelating agent, an amino acid-based chelating agent, an ether polycarboxylic acid-based chelating agent, a phosphonic acid-based chelating agent, a hydroxycarboxylic acid-based chelating agent, a phosphoric acid-based chelating agent, a polymer electrolyte-based chelating agent, dimethyl glyoxime (DG), or a combination thereof.

For example, the chelating agent may be formed of iminodimethyl phosphonic acid (IDP), alkyl diphosphonic acid (ADPA), ethylenediaminetetraacetic acid (EDTA), cyclohexanediaminetetraacetic acid (CDTA), nitrilotriacetic acid (NTA), ethylenediamine, dimercaprol, citric acid, dithiooxamide, diphenylthiocarbazide, dithiozone, cupferron, petane-2,4-dione, iminodiacetic acid (IDA), N-(2-hydroxyethyl)iminodiacetic acid (HIMDA), diethylenetriaminepentaacetic acid (DTPA), N-(2-hydroxyethyl)ethylenediaminetriacetic acid (EDTA-OH), glycoletherdiaminetetraacetic acid (GEDTA), sodium ethylenediaminetetraacetate, sodium nitrilotriacetate, ammonium nitrilotriacetate, hydroxyethyl ethylenediaminetriacetic acid, sodium hydroxyethyl ethylenediaminetriacetate, diethylenetriaminepentaacetic acid, sodium diethylenetriaminepentaacetate, triethylenetetraminehexaacetic acid, sodium triethylenetetraaminehexaacetate, or a combination thereof, but the present invention is not limited thereto.

The content of the chelating agent in the first substrate processing composition may be about 0.01 mass % to about 15 mass % relative to the total mass of the first substrate processing composition.

In the substrate processing method according to the present embodiment, the second substrate processing step S34 using the second substrate processing composition is performed after the first substrate processing step S32 described above. The second substrate processing step S34 may be continuously performed in-situ after the first substrate processing step S32 of removing the edge bead portion of the metal-containing resist film applied on the substrate.

As the second substrate processing composition used in the second substrate processing step S34, the above-described substrate processing composition used in the edge rinsing step S30 of FIG. 1 may be used. That is, the second substrate processing composition contains the organic solvent, the organic acid, and the chelating additive represented by Chemical Formula 1. As described above, since the chelating additive represented by Chemical Formula 1 contained in the second substrate processing composition has at least three or more chelating sites, metal elements or metallic impurities containing metal elements that may reside on the exposed edge portion of the substrate or the surface of equipment around the substrate after the first substrate processing step S32 can be effectively removed.

In another exemplary embodiments, the second substrate processing composition may further contain at least one additional compound selected from an alcohol compound, H₂O₂, and HF. The content of the additional compound in the second substrate processing composition may be about 0.5 wt % to about 90 wt %, or about 0.5 wt % to about 20 wt %.

The alcohol compound may be selected from ethanol, propanol, isopropyl alcohol, isobutyl alcohol, hexanol, ethylene glycol, 1,2-propanediol (propylene glycol), 1,3-propanediol, 1,4-pentanediol, 1,5-pentanediol, 1,2-butanediol, 1,4-butanediol, 1,3-butanediol, catechol, methylcatechol, ethylcatechol, t-butylcatechol, and a combination thereof.

When the second substrate processing composition further contains at least one additional compound selected from an alcohol compound, H₂O₂, and HF, the additional compound, may serve to remove metal elements or metallic impurities that may reside on the exposed surface of the substrate or the surface of process equipment after the edge bead portion is removed, by reacting with the metal elements or the metallic impurities similarly to the organic acid included in the second substrate processing composition.

In sone embodiments, the second substrate processing composition may further contain at least one inorganic acid selected from nitric acid, sulfuric acid, HCl, phosphoric acid, hexafluorosilicic acid, hexafluorophosphoric acid, fluoroboric acid, and a combination thereof.

In another exemplary embodiments, the second substrate processing composition may further contain a surfactant. A detailed configuration of the surfactant is substantially the same as described for the surfactant that may be contained in the substrate processing composition used in the substrate processing method of FIG. 1. The content of the surfactant in the second substrate processing composition may be about 0.01 mass % to about 15 mass % relative to the total mass of the second substrate processing composition.

The substrate processing method according to the embodiment of FIG. 2 may optionally include the third substrate processing step S36 using the third substrate processing composition. In the case of performing the third substrate processing step S36, this may be continuously performed in situ after performing the second substrate processing step S34.

By supplying the third substrate processing composition to the edge portion of the substrate, residues of the second substrate processing composition remaining on the edge portion of the substrate after the second substrate processing step S34 may be removed from the substrate. For example, it is possible to effectively remove reactive impurities such as acid residues derived from the second substrate processing composition that may reside on the exposed surface of the edge portion of the substrate and the surface of process equipment therearound.

The third substrate processing composition used for this may have the same composition as the first substrate processing composition, and more preferably contains only an organic solvent. For example, the organic solvent of the third substrate processing composition may consist of a combination of PGME and PGMEA, and in this case, the weight ratio of PGME and PGMEA in the organic solvent may be about 3:7 to 5:5, more preferably may be about 4:6.

Although not shown in FIG. 2, after the second substrate processing step S34 or third substrate processing step S36 is performed, a drying step may be performed to remove the second substrate processing composition or third substrate processing composition residing on the edge of the substrate.

In the embodiment of FIG. 2, the edge bead is mainly removed through the first substrate processing step S32, and the metal elements residing on the substrate surface exposed by the removal of the edge bead are removed through the second substrate processing step S34, and optionally, the acid residue of the second substrate processing composition residing on the surface of the exposed substrate is removed through the third substrate processing step S36, but, the present invention is not limited thereto.

For example, as a modification, the first substrate processing step may be omitted in the substrate processing method of FIG. 2, and the edge bead is mainly removed by the second substrate processing composition, and the surface of the substrate exposed by removing the edge bead may be cleaned through the third substrate processing step. According to this modification, since the first substrate processing step can be omitted, the substrate processing method can be further simplified and productivity can be improved.

As described above, according to the substrate processing method pertaining to the technical spirit of the present invention, in the lithography process using the metal-containing resist composition, it is possible to increase process efficiency by suppressing substrate contamination and facility contamination due to metal derived from the metal-containing resist composition. Deterioration of the electrical properties of the semiconductor device can be prevented. Furthermore, the influence on the underlying film formed on the substrate can be reduced, and the stability (solubility) of the substrate processing composition over time can be improved.

Hereinafter, substrate processing examples using the substrate processing composition of the present invention will be described, but the present invention is not limited thereto. Components shown in Table 1 are mixed to prepare the substrate processing composition for each example.

TABLE 1

| Substrate | | | | | | | | |
|---|---|---|---|---|---|---|---|---|
| Composition | Organic | Acid | | | Chelate | | | |
| Processing | Solvent | AA | FA | PA | IDP | ADPA | EDTA | QC |
| Example 1 | 89.5 | 10 | | | | | | 0.5 |
| Example 2 | 89.5 | 10 | | | | | | 0.5 |
| Example 3 | 89.5 | | 10 | | | | | 0.5 |
| Example 4 | 89 | | | 10 | | | | 1 |
| Example 5 | 89.5 | | | 10 | | | | 0.5 |
| Comparative | 80 | | 20 | | | | | |
| Example 1 | | | | | | | | |
| Comparative | 79 | 20 | | | 1 | | | |
| Example 2 | | | | | | | | |
| Comparative | 79 | 20 | | | | 1 | | |
| Example 3 | | | | | | | | |
| Comparative | 79 | 20 | | | | | 1 | |
| Example 4 | | | | | | | | |

Organic Solvent: Mixed Solvent (PGME/PGMEA = 70/30)
AA: Acetic acid
FA: Formic acid
PA: Phosphoric acid
IDP: iminodimethyl phosphonic acid
ADPA: alkyl diphosphonic acid)
EDTA: ethylenediaminetetraacetic acid
QC: Quercetin

Compositions of Examples 1 to 5 and Comparative Examples 1 to 4 were prepared and stirred at room temperature for about 1 hour, and then wafers coated with organometallic tin oxyhydroxide resist were immersed in the compositions for 1 minute. The surfaces of the wafers from which the organometallic tin oxyhydroxide resist was removed by the compositions were analyzed by the VDP-IPC method to measure the amount of Sn on the surface. When the residual amount of surface Sn is not more than 5.00E+10 atoms/cm², it is indicated as O, and when the residual amount of surface Sn exceeds 5.00E+10 atoms/cm², it is indicated as X in Table 2.

Compositions of Examples 1 to 5 and Comparative Examples 1 to 4 were prepared and stirred at room temperature for about 1 hour, and then wafers on which nitride and poly-Si were deposited were immersed in the prepared compositions for 5 minutes. The thickness change before and after immersing the wafers on which nitride and poly-Si were deposited into the compositions were measured by ellipsometer analysis. When the thickness change of nitride and poly-Si is less than 5 Å, it is indicated as O, and when the thickness change of nitride and poly-Si exceeds 5 Å, it is indicated as X in Table 2.

Compositions of Examples 1 to 5 and Comparative Examples 1 to 4 were prepared and stirred at room temperature for about 1 hour, and then the solubility of the composition was visually observed. In the case where there is no residue in the lower part of the composition and the upper part is dissolved well without layer separation, it is indicated as O, and in the case of poor solubility due to residue or suspended matter, it is indicated as X in Table 2.

TABLE 2
Substrate

| Processing | Sn | Influence on Underlying Film | | |
|---|---|---|---|---|
| Composition | Removability | Nitride | Poly-Si | Solubility |
| Example 1 | ◯ | ◯ | ◯ | ◯ |
| Example 2 | ◯ | ◯ | ◯ | ◯ |
| Example 3 | ◯ | ◯ | ◯ | ◯ |
| Example 4 | ◯ | ◯ | ◯ | ◯ |
| Example 5 | ◯ | ◯ | ◯ | ◯ |
| Comparative | ◯ | ◯ | X | ◯ |
| Example 1 | | | | |
| Comparative | ◯ | ◯ | X | ◯ |
| Example 2 | | | | |
| Comparative | X | ◯ | ◯ | ◯ |
| Example 3 | | | | |
| Comparative | X | ◯ | ◯ | X |
| Example 4 | | | | |

As shown in Table 2, the substrate processing composition according to an embodiment of the present invention has exhibited improvements, compared to the comparative examples, not only in metal (tin) removability, but also in the influence on the underlying film and stability (solubility) over time.

In the above, the present invention has been described in detail with preferred embodiments, but the present invention is not limited to the above embodiments, and various modifications and changes may be made by those skilled in the art within the technical spirit and scope of the present invention.

1. A substrate processing composition for processing a substrate coated with a metal-containing resist composition, comprising:
an organic solvent, an organic acid and an additive,
wherein the additive comprises a chelating agent represented by Chemical Formula 1: 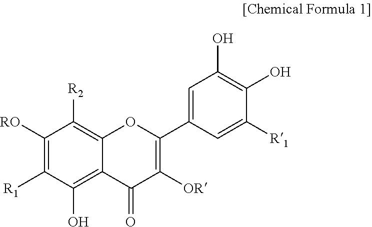
(In Chemical Formula 1,
R₁, R₂ and R′₁ are the same or different at each instance, and are independently hydrogen or a hydroxy group,
R and R′ are the same or different at each instance, and are independently hydrogen, a sulfate group, or a substituted or unsubstituted C1-C30 aliphatic or aromatic hydrocarbon group, and
at least one hydrogen of R and R′ may be substituted by a hydroxyl group.)

2. The substrate processing composition of claim 1, wherein the content of the additive ranges 0.1 to 10% by mass relative to the total mass of the substrate processing composition.

3. The substrate processing composition of claim 1, wherein the organic acid comprises formic acid, acetic acid, citric acid, oxalic acid, 2-nitrophenylacetic acid, 2-ethylhexanoic acid, dodecanoic acid, ascorbic acid, tartaric acid, glucuronic acid, methane sulfonic acid, benzenesulfonic acid, p-toluene sulfonic acid or a mixture thereof.

4. The substrate processing composition of claim 1, wherein the content of the organic acid ranges 10 to 60% by mass relative to the total mass of the substrate processing composition.

5. The substrate processing composition of claim 1, wherein the organic solvent comprises a glycol ether or an ester thereof, an alcohol, a ketone, a liquid cyclic carbonate, or a mixture thereof.

6. The substrate processing composition of claim 5, wherein the organic solvent includes propylene glycol methyl ether (PGME), propylene glycol methyl ethyl acetate (PGMEA), or a mixture thereof.

7. A substrate processing method comprising steps of:
applying a metal-containing resist composition on a substrate;
processing the substrate using the substrate processing composition of claim 1; and
forming a pattern of a metal-containing resist film on the substrate.

8. The substrate processing method of claim 7, wherein the step of processing the substrate includes a step of removing at least a portion of the metal-containing resist composition applied on the substrate with the substrate processing composition.

9. The substrate processing method of claim 7, wherein
the step of processing the substrate includes a first substrate processing step of processing the substrate using a first substrate processing composition and a second substrate processing step of processing the substrate using a second substrate processing composition,
the first substrate processing composition contains an organic solvent, and
the substrate processing composition is used as the second substrate processing composition.

10. The substrate processing method of claim 9, wherein the organic solvent contained in the first substrate processing composition includes propylene glycol methyl ether (PGME), propylene glycol methyl ethyl acetate (PGMEA), or a mixture thereof.

11. The substrate processing method of claim 9, wherein the step of processing the substrate further includes a third substrate processing step of processing the substrate using a third substrate processing composition after the second substrate processing step, and
wherein the third substrate processing composition comprises only an organic solvent including propylene glycol methyl ether (PGME), propylene glycol methyl ethyl acetate (PGMEA), or a mixture thereof.

12. The substrate processing method of claim 7, wherein
the step of processing the substrate includes a first substrate processing step of processing a substrate using a first substrate processing composition and a second substrate processing step of processing a substrate using a second substrate processing composition,
as the first substrate processing composition, the substrate processing composition is used, and
the second substrate processing composition consists only of an organic solvent.

13. The substrate processing method of claim 12, wherein the organic solvent of the second substrate processing composition comprises propylene glycol methyl ether (PGME), propylene glycol methyl ethyl acetate (PGMEA) or a mixture thereof.

14. The substrate processing method of claim 7, wherein
the metal-containing resist composition has a metal structure including an organometallic compound, organometallic nanoparticles, or organometallic clusters; and
the metal structure has a metal core containing at least one metal atom, and at least one organic ligand coordinating the metal core.

15. The substrate processing method of claim 7, wherein the step of forming the pattern of the metal-containing resist film comprises a step of exposing the substrate on which the metal-containing resist film is formed to extreme ultraviolet (EUV) or an electron beam.
